(19) United States
(12) Patent Application Publication
(10) Pub. No.: US 2026/0231794 A1
(43) Pub. Date: Aug. 6, 2026

(54) SEMICONDUCTOR STRUCTURE

(71) Applicant: UNITED MICROELECTRONICS CORP., Hsin-Chu City (TW)

(72) Inventors: Meng-Ting Chiang, Taichung City (TW); Kai-Kuang Ho, Hsinchu City (TW); Jen-Hsien Chang, Taichung City (TW)

(73) Assignee: UNITED MICROELECTRONICS CORP., Hsin-Chu City (TW)

(21) Appl. No.: 19/063,251

(22) Filed: Feb. 25, 2025

(30) Foreign Application Priority Data
Feb. 3, 2025 (TW) 114103752

(51) Int. Cl. H01L 23/498

(52) U.S. Cl. CPC H10W 70/65; H10W 70/69

(57) ABSTRACT

A semiconductor structure includes a substrate, a top metal layer disposed on the substrate, a top dielectric layer disposed on the substrate and the top metal layer, at least one opening disposed in the top dielectric layer, and an aluminum layer conformally deposited on the top dielectric layer and in the at least one opening. When viewed from above, the at least one opening has a regular n-gon pattern (n is greater than or equal to 6), circular pattern or oval pattern.

### BACKGROUND OF THE INVENTION

### 1. Field of the Invention

This invention relates to the field of semiconductor technology, and particularly to a semiconductor structure suitable for use in embedded high voltage (eHV) devices and processes.

### 2. Description of the Prior Art

In the embedded high voltage (eHV) process, square openings are designed in the top dielectric layer covering the top metal traces, exposing portions of the top metal traces. However, these square openings lead to problems with poor step coverage of the subsequently filled aluminum metal layer and passivation layer at the corners of the square openings. The passivation layer develops cracks, and in the subsequent wet etching process, acid penetrates from the cracks, causing the underlying aluminum metal layer to be over-etched.

Therefore, there is still a need in the art for an improved semiconductor structure to address the aforementioned technical problems.

### SUMMARY OF THE INVENTION

It is one objective of the present invention to provide an improved semiconductor structure suitable for use in embedded high-voltage (eHV) devices and processes, in order to overcome the shortcomings or deficiencies of the prior art.

One aspect of the invention provides a semiconductor structure including a substrate; a top metal layer disposed on the substrate; a top dielectric layer disposed on substrate and the top metal layer; at least one opening in the top dielectric layer; and an aluminum layer conformally deposited on the top dielectric layer and in the at least one opening, wherein the at least one opening has a regular n-sided polygonal pattern (where n is greater than or equal to 6), a circular pattern, or an oval pattern when viewed from above.

According to some embodiments, the aluminum layer is in direct contact with the top metal layer.

According to some embodiments, the aluminum layer conformally covers a sidewall of the at least one opening and a bottom surface of the at least one opening, thereby forming a recessed region above the at least one opening.

According to some embodiments, the at least one opening partially exposes a top surface of the top metal layer.

According to some embodiments, the aluminum layer is in direct contact with the top metal layer through the at least one opening.

According to some embodiments, the semiconductor structure further includes a passivation layer conformally covers the aluminum layer and the recessed region above the at least one opening, wherein an included angle between a sidewall and a top surface of the passivation layer within the recessed region is greater than or equal to 80 degrees.

According to some embodiments, he passivation layer comprises a silicon oxide layer or a phosphosilicate glass layer.

According to some embodiments, the passivation layer comprises a silicon nitride layer on the silicon oxide layer or the phosphosilicate glass layer.

According to some embodiments, the top metal layer comprises tungsten.

According to some embodiments, the top metal layer comprises copper.

Another aspect of the invention provides a semiconductor structure including a substrate; a first top metal layer disposed on the substrate; a second top metal layer disposed on the substrate, wherein the second top metal layer is spaced apart from the first top metal layer; a top dielectric layer disposed on the first top metal layer, the second top metal layer, and the substrate; at least one first opening in the top dielectric layer; at least one second opening in the top dielectric layer; a first aluminum layer conformally deposited on the top dielectric layer and in the at one first opening; and a second aluminum layer conformally deposited on the top dielectric layer and in the at least one second opening, wherein each of the at least one first opening and the at least one second opening has a regular n-sided polygonal pattern (where n is greater than or equal to 6), a circular pattern, or an oval pattern when viewed from above.

According to some embodiments, the first aluminum layer is in direct contact with the first top metal layer and the second aluminum layer is in direct contact with the second top metal layer.

According to some embodiments, the first aluminum layer conformally covers a sidewall of the at least one first opening and a bottom surface of the at least one first opening, thereby forming a first recessed region above the at least one first opening, and wherein the second aluminum layer conformally covers a sidewall of the at least one second opening and a bottom surface of the at least one second opening, thereby forming a second recessed region above the at least one second opening.

According to some embodiments, the at least one first opening partially exposes a top surface of the first top metal layer and the at least one second opening partially exposes a top surface of the second top metal layer.

According to some embodiments, the first aluminum layer and the second aluminum layer are in direct contact with the top surface of the first top metal layer and the top surface of the second metal layer through the at least one first opening and the at least one second opening, respectively.

According to some embodiments, the semiconductor structure further includes a passivation layer conformally covers the first aluminum layer, the second aluminum layer, the first recessed region, and the second recessed region, wherein an included angle between a sidewall and a top surface of the passivation layer within the first recessed region or the second recessed region is greater than or equal to 80 degrees.

According to some embodiments, the passivation layer comprises a silicon oxide layer or a phosphosilicate glass layer.

According to some embodiments, the passivation layer comprises a silicon nitride layer on the silicon oxide layer or the phosphosilicate glass layer.

According to some embodiments, the first top metal layer and the second top metal layer comprise tungsten.

According to some embodiments, the first top metal layer and the second top metal layer comprise copper.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top perspective view of a semiconductor structure in accordance with an embodiment of the present invention.

FIG. 2 is a cross-sectional view taken along line I-I′ in FIG. 1.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

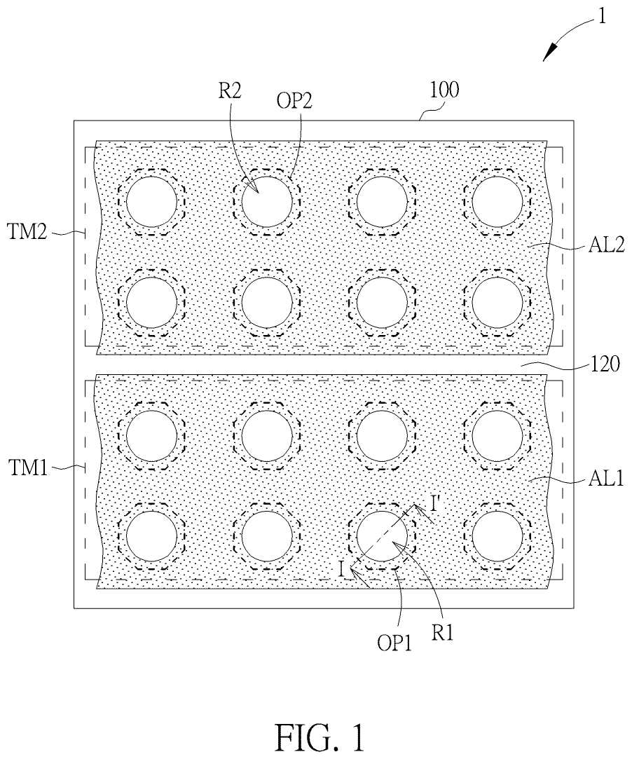

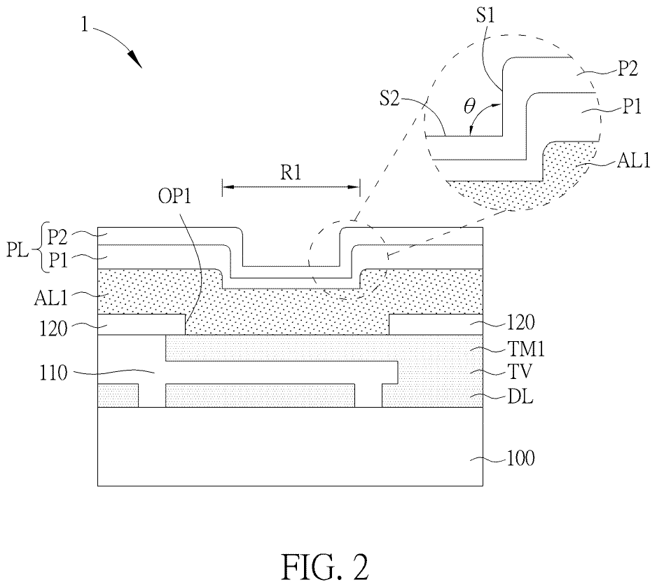

Please refer to FIG. 1 and FIG. 2, wherein FIG. 1 is a top perspective view of a semiconductor structure according to an embodiment of the present invention, and FIG. 2 is a cross-sectional view taken along the cutting line I-I′ in FIG. 1. As shown in FIG. 1 and FIG. 2, the semiconductor structure 1 includes a substrate 100, such as a silicon substrate, but is not limited thereto. According to an embodiment of the present invention, at least one inter-metal dielectric layer 110 such as a low-k material layer or an ultra-low-k material layer is disposed on the substrate 100, and at least one lower metal layer DL is disposed in the at least one inter-metal dielectric layer 110. According to an embodiment of the present invention, the at least one lower metal layer DL is, for example, an embedded copper metal layer, but is not limited thereto.

According to an embodiment of the present invention, a first top metal layer TM1 and a second top metal layer TM2 are disposed on the substrate 100. The second top metal layer TM2 may be spaced apart from the first top metal layer TM1. According to an embodiment of the present invention, the first top metal layer TM1 and the second top metal layer TM2 are, for example, embedded copper metal layers, but are not limited thereto. According to an embodiment of the present invention, the first top metal layer TM1 and the second top metal layer TM2 are in the uppermost copper metal layer of the copper metal interconnect structure of the semiconductor structure 1. According to some embodiments of the present invention, the first top metal layer TM1 and the second top metal layer TM2 may include tungsten.

According to an embodiment of the present invention, a top dielectric layer 120 is formed on the first top metal layer TM1 and the second top metal layer TM2. For example, the top dielectric layer 120a may be a silicon oxide layer or a silicon nitride layer, but it is not limited thereto. As can be seen from FIG. 2, the first top metal layer TM1 is electrically connected to the at least one lower metal layer DL through a conductive via TV.

According to an embodiment of the present invention, at least one first opening OP1 and at least one second opening OP2 are formed in the top dielectric layer 120. The at least one first opening OP1 and the at least one second opening OP2 are respectively located directly above the first top metal layer TM1 and the second top metal layer TM2, and respectively expose the top surface of the first top metal layer TM1 and the top surface of the second top metal layer TM2. According to an embodiment of the present invention, when viewed from above, as shown in FIG. 1, the at least one first opening OP1 or the at least one second opening OP2 has, for example, a regular octagon pattern, but is not limited thereto. In other embodiments, when viewed from above, the at least one first opening OP1 or the at least one second opening OP2 may have a regular n-sided polygon pattern (where n is greater than or equal to 6), a circular pattern, or an oval pattern.

According to an embodiment of the present invention, a first aluminum layer AL1 is provided on the top dielectric layer 120. The first aluminum layer AL1 is conformally deposited on the top dielectric layer 120 and in the at least one first opening OP1. The second aluminum layer AL2 is conformally deposited on the top dielectric layer 120 and in the at least one second opening OP2. According to an embodiment of the present invention, the first aluminum layer AL1 and the second aluminum layer AL2 are spaced apart from each other. According to an embodiment of the present invention, the first aluminum layer AL1 is in direct contact with the top surface of the first top metal layer TM1 through the at least one first opening OP1, and the second aluminum layer AL2 is in direct contact with the top surface of the second top metal layer TM2 through the at least one second opening OP2.

According to an embodiment of the present invention, the first aluminum layer AL1 conformally covers the sidewall of the at least one first opening OP1 and the bottom surface of at least one first opening OP1, thereby forming a first recessed region R1 above the at least one first opening OP1. Likewise, the second aluminum layer AL2 conformally covers the sidewall of at least one second opening OP2 and the bottom surface of at least one second opening OP2, thereby forming a second recessed region R2 above the at least one second opening OP2.

According to an embodiment of the present invention, the semiconductor structure 1 further includes a passivation layer PL, conformally covering the first aluminum layer AL1, the second aluminum layer AL2, the first recessed region R1, and the second recessed region R2. According to an embodiment of the present invention, the passivation layer PL may include a lower layer P1 such as a silicon oxide layer or a phosphosilicate glass (PSG) layer. According to an embodiment of the present invention, the passivation layer PL may further include a silicon nitride layer P2 over the lower layer P1. As shown in the enlarged view of FIG. 2, the angle θ between the sidewall S1 and the top surface S2 of the passivation layer PL within the first recessed region R1 or the second recessed region R2 is greater than or equal to 80 degrees. Therefore, the passivation layer PL has better step coverage within the at least one first opening OP1 or the at least one second opening OP2, which can avoid cracks during the subsequent wet etching process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate;
a top metal layer disposed on the substrate;
a top dielectric layer disposed on substrate and the top metal layer;
at least one opening in the top dielectric layer; and
an aluminum layer conformally deposited on the top dielectric layer and in the at least one opening, wherein the at least one opening has a regular n-sided polygonal pattern (where n is greater than or equal to 6), a circular pattern, or an oval pattern when viewed from above.

2. The semiconductor structure according to claim 1, wherein the aluminum layer is in direct contact with the top metal layer.

3. The semiconductor structure according to claim 1, wherein the aluminum layer conformally covers a sidewall of the at least one opening and a bottom surface of the at least one opening, thereby forming a recessed region above the at least one opening.

4. The semiconductor structure according to claim 1, wherein the at least one opening partially exposes a top surface of the top metal layer.

5. The semiconductor structure according to claim 4, wherein the aluminum layer is in direct contact with the top metal layer through the at least one opening.

6. The semiconductor structure according to claim 3 further comprising:
a passivation layer conformally covers the aluminum layer and the recessed region above the at least one opening, wherein an included angle between a sidewall and a top surface of the passivation layer within the recessed region is greater than or equal to 80 degrees.

7. The semiconductor structure according to claim 6, wherein the passivation layer comprises a silicon oxide layer or a phosphosilicate glass layer.

8. The semiconductor structure according to claim 7, wherein the passivation layer comprises a silicon nitride layer on the silicon oxide layer or the phosphosilicate glass layer.

9. The semiconductor structure according to claim 1, wherein the top metal layer comprises tungsten.

10. The semiconductor structure according to claim 1, wherein the top metal layer comprises copper.

11. A semiconductor structure, comprising:
a substrate;
a first top metal layer disposed on the substrate;
a second top metal layer disposed on the substrate, wherein the second top metal layer is spaced apart from the first top metal layer;
a top dielectric layer disposed on the first top metal layer, the second top metal layer, and the substrate;
at least one first opening in the top dielectric layer;
at least one second opening in the top dielectric layer;
a first aluminum layer conformally deposited on the top dielectric layer and in the at least one first opening; and
a second aluminum layer conformally deposited on the top dielectric layer and in the at least one second opening, wherein each of the at least one first opening and the at least one second opening has a regular n-sided polygonal pattern (where n is greater than or equal to 6), a circular pattern, or an oval pattern when viewed from above.

12. The semiconductor structure according to claim 11, wherein the first aluminum layer is in direct contact with the first top metal layer and the second aluminum layer is in direct contact with the second top metal layer.

13. The semiconductor structure according to claim 11, wherein the first aluminum layer conformally covers a sidewall of the at least one first opening and a bottom surface of the at least one first opening, thereby forming a first recessed region above the at least one first opening, and wherein the second aluminum layer conformally covers a sidewall of the at least one second opening and a bottom surface of the at least one second opening, thereby forming a second recessed region above the at least one second opening.

14. The semiconductor structure according to claim 11, wherein the at least one first opening partially exposes a top surface of the first top metal layer and the at least one second opening partially exposes a top surface of the second top metal layer.

15. The semiconductor structure according to claim 14, wherein the first aluminum layer and the second aluminum layer are in direct contact with the top surface of the first top metal layer and the top surface of the second metal layer through the at least one first opening and the at least one second opening, respectively.

16. The semiconductor structure according to claim 13 further comprising:
a passivation layer conformally covers the first aluminum layer, the second aluminum layer, the first recessed region, and the second recessed region, wherein an included angle between a sidewall and a top surface of the passivation layer within the first recessed region or the second recessed region is greater than or equal to 80 degrees.

17. The semiconductor structure according to claim 16, wherein the passivation layer comprises a silicon oxide layer or a phosphosilicate glass layer.

18. The semiconductor structure according to claim 17, wherein the passivation layer comprises a silicon nitride layer on the silicon oxide layer or the phosphosilicate glass layer.

19. The semiconductor structure according to claim 11, wherein the first top metal layer and the second top metal layer comprise tungsten.

20. The semiconductor structure according to claim 11, wherein the first top metal layer and the second top metal layer comprise copper.
